(19) United States
(12) Patent Application Publication
(10) Pub. No.: US 2016/0020111 A1
(43) Pub. Date: Jan. 21, 2016

(54) MANUFACTURING METHOD OF SEMICONDUCTOR DEVICE

(71) Applicant: KABUSHIKI KAISHA TOSHIBA, Minato-ku (JP)

(72) Inventor: Yuuko JIMMA, Yokkaichi (JP)

(73) Assignee: KABUSHIKI KAISHA TOSHIBA, Minato-ku (JP)

(21) Appl. No.: 14/482,349

(22) Filed: Sep. 10, 2014

Related U.S. Application Data
(60) Provisional application No. 62/025,807, filed on Jul. 17, 2014.

(51) Int. Cl. H01L 21/308

(52) U.S. Cl. CPC H01L 21/3086

(57) ABSTRACT

In a manufacturing method of a semiconductor device according to an embodiment, a mask material comprising at least one layer of a hafnium silicate (HfSiOn (n is a positive number)) film is formed on a processing target film. The processing target material is processed using the mask material as a mask. The hafnium silicate film is located almost at a central portion of the mask material or between the central portion of the mask material and an upper surface thereof.

### CROSS REFERENCE TO RELATED APPLICATIONS

This application is based upon and claims the benefit of priority from the prior U.S. Provisional Patent Application No. 62/025,807, filed on Jul. 17, 2014, the entire contents of which are incorporated herein by reference.

### FIELD

The embodiments of the present invention relate to a manufacturing method of a semiconductor device.

### BACKGROUND

Semiconductor devices have been increasingly downscaled and the widths, of lines and spaces processed in a semiconductor manufacturing step have become narrower. As the line width becomes narrower, the mask width also becomes narrower and thus the mask material is likely to be etched at the time of processing a processing target material. Accordingly, when the line width becomes narrower, a film thickness of the mask material required in a processing step of the processing target material becomes larger.

Meanwhile, when the film thickness of the mask material becomes larger, an aspect ratio of the mask material and the processing target material becomes higher. This causes processing of the processing target material to be more difficult. Furthermore, a higher aspect ratio leads to collapse of a line pattern of the mask material and the processing target material.

To address this problem, an etching rate (a selection ratio) of the processing target material to the mask material can be increased. This enables to reduce the film thickness of the mask material and lower the aspect ratio.

However, an increase in the etching rate of the processing target material implies that more reaction products are generated when the processing target material is etched. Therefore, when the etching rate of the processing target material is increased, a large quantity of reaction products adheres to the mask material and the reaction products may close opening parts of the mask material.

As mentioned above, increasing the etching rate of the processing target material for the purpose of reducing the film thickness of the mask material and suppressing closing of the opening parts of the mask material have a trade-off relation.

### BRIEF DESCRIPTION OF THE DRAWINGS

FIGS. 1 to 6 are cross-sectional views showing an example of a manufacturing method of a semiconductor device according to a first embodiment;

FIG. 7 is a cross-sectional view showing an example of a manufacturing method of a semiconductor device according to a modification of the first embodiment; and

FIGS. 8 to 12 are cross-sectional views showing an example of a manufacturing method of a semiconductor device according to a second embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction of a surface of a substrate on which semiconductor elements are provided is assumed as “an upper direction”. Therefore, the term “upper direction” or “lower direction” occasionally differs from an upper direction or a lower direction based on a gravitational acceleration direction.

In a manufacturing method of a semiconductor device according to an embodiment, a mask material comprising at least one layer of a hafnium silicate (HfSiOn (n is a positive number)) film is formed on a processing target film. The processing target material is processed using the mask material as a mask. The hafnium silicate film is located almost at a central portion of the mask material or between the central portion of the mask material and an upper surface thereof.

### First Embodiment

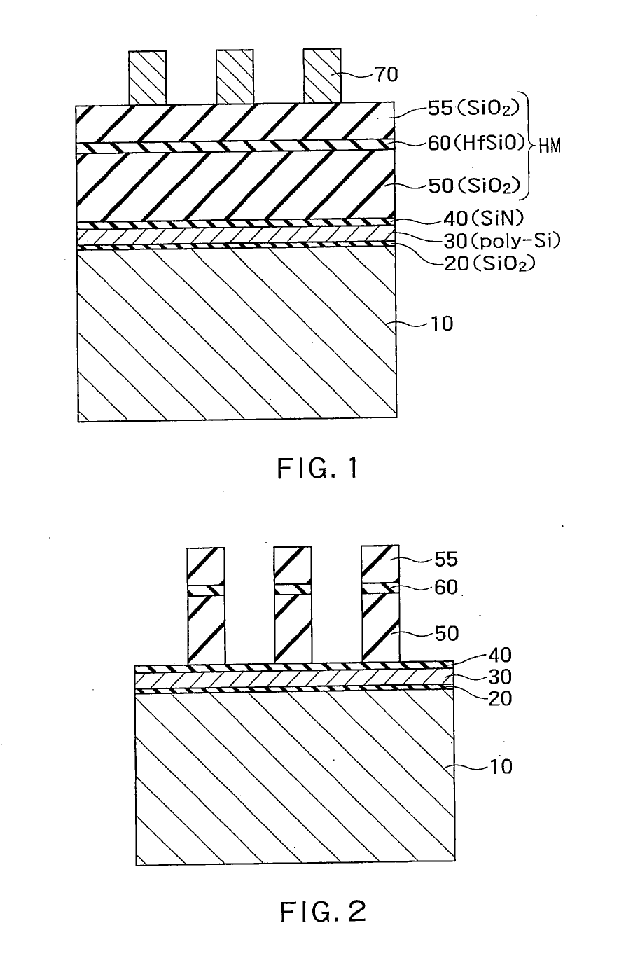

FIGS. 1 to 6 are cross-sectional views showing an example of a manufacturing method of a semiconductor device according to a first embodiment. The method according to the present embodiment is applied to a formation step of gate electrodes (a charge accumulation layer) and STIs (Shallow Trench Isolations). However, the present embodiment is applicable to other lithography and etching steps. The present embodiment is applicable to a NAND flash memory and is also applicable to any other semiconductor devices such as an LSI (Large Scale Integration). An example in which the present embodiment is applied to a NAND flash memory is shown below.

A gate dielectric film 20 is first deposited on a substrate 10. The gate dielectric film 20 is an insulating film such as a silicon dioxide film, a silicon nitride film, or a high dielectric film (HfO₂, for example) having a higher relative permittivity than a silicon dioxide film. The gate dielectric film 20 can be formed by thermally oxidizing the substrate 10 or can be formed by being deposited on the substrate 10.

A polysilicon film 30 is then deposited on the gate dielectric film 20.

A silicon nitride film 40 is then deposited on the polysilicon film 30. The silicon nitride film 40 functions as an etching stopper at later steps.

The silicon nitride film 40, the polysilicon film 30, the silicon dioxide film 20, and/or the substrate 10 are a processing target material.

A silicon dioxide film 50 is then deposited on the silicon nitride film 40. The silicon dioxide film 50 is formed as a part (first mask material) of a mask material.

A hafnium silicate (HfSiOn (n is a positive number)) film 60 is then deposited on the silicon dioxide film 50. The hafnium silicate film 60 is formed as a part of the mask material.

A silicon dioxide film 55 is then deposited on the hafnium silicate film 60. The silicon dioxide film 55 is formed as another part (second mask material) of the mask material.

As described above, the mask material is a stacked layer film including the silicon dioxide film 50 being the first mask material, the hafnium silicate film 60, and the silicon dioxide film 55 being the second mask material. The mask material is hereinafter also referred to as “hard mask HM”. The hard mask HM has a structure in which at least one layer of the hafnium silicate film 60 is provided between the silicon dioxide films 50 and 55. The hafnium silicate film 60 is formed in the hard mask HM as a layer substantially parallel to a surface of the substrate 10. For example, when a line width (or a space width) is about 10 nanometers to 20 nanometers, the hard mask HM has a thickness of, for example, about 100 nanometers to 150 nanometers and the hafnium silicate film 60 has a thickness of, for example, about 5 nanometers to several tens of nanometers. The hafnium silicate film 60 is harder to etch than a silicon dioxide film and thus it is difficult to form the hafnium silicate film 60 thick. Therefore, the entire hard mask HM cannot be formed of the hafnium silicate film 60 and the hafnium silicate film 60 needs to be formed as a part of the hard mask HM. A formation position of the hafnium silicate film 60 will be explained later.

A resist 70 is then formed on the hard mask HM by a lithography technique. The resist 70 is formed on areas where the hard mask HM is to be left. For example, the resist 70 is processed in a line-and-space pattern to form the STIs and the charge accumulation layer. A structure shown in FIG. 1 is thereby obtained.

The hard mask HM is then etched by a RIE (Reactive Ion Etching) method using the resist 70 as a mask. At that time, the silicon nitride film 40 functions as an etching stopper. The resist 70 is then removed using O₂ plasma or the like. A structure shown in FIG. 2 is thereby obtained.

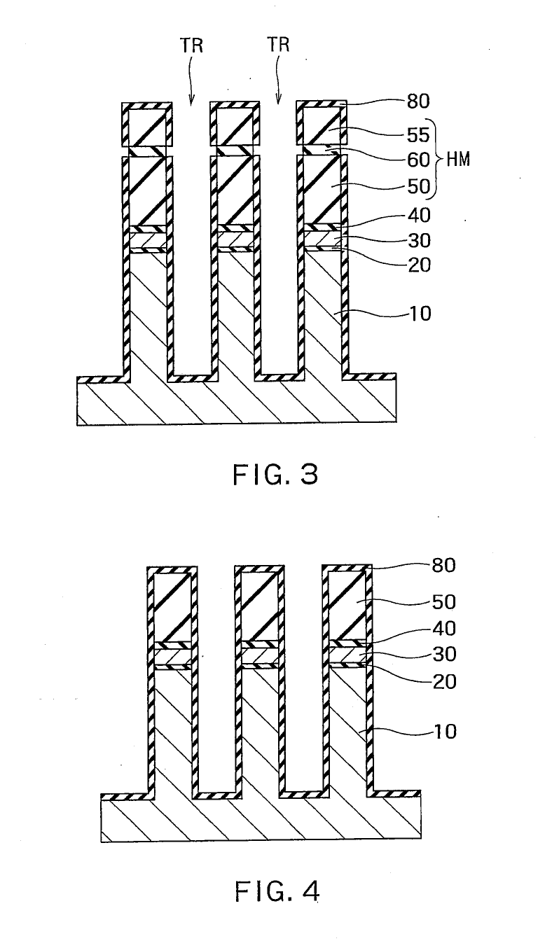

The silicon nitride film 40, the polysilicon film 30, the gate dielectric film 20, and the substrate 10 (hereinafter, also collectively as “processing target material”) are then etched by the RIE method using the hard mask HM as a mask. Reaction products are generated when the processing target material is etched and the reaction products adhere to side walls of trenches TR as deposits (etching residues) 80 as shown in FIG. 3. Etching gas contains at least HBr and O₂ and is, for example, CF-based gas. In this case, the deposits 80 are CF-based deposits and deposits containing a silicon oxide.

In this case, as shown in FIG. 3, the deposits 80 adhering to the hafnium silicate film 60 are fewer than those adhering to other surface areas of the hard mask HM. That is, the deposits 80 adhering to the hafnium silicate film 60 have a film thickness smaller than that of the deposits 80 adhering to the silicon dioxide films 50 and 55. Almost no deposits 80 possibly adhere to portions where the hafnium silicate film 60 is provided. Therefore, by providing the hafnium silicate film 60 at parts of the hard mask HK, which are easily closed by the deposits 80, closing of opening parts of the hard mask HM can be suppressed.

In the present embodiment, the hafnium silicate film 60 is located almost at a central portion of the hard mask HM or between the central portion of the hard mask HM and an upper surface thereof in the thickness direction of the hard mask HM. For example, as shown in FIG. 1, the hafnium silicate film 60 is located slightly above the central portion of the hard mask HM.

If the hafnium silicate film 60 is provided near the upper surface of the hard mask HM, the hafnium silicate film 60 may be lost at the beginning of a processing step of the processing target material. In this case, after the loss of the hafnium silicate film 60, the hard mask HM is inevitably formed only of the silicon dioxide film 50 and thus openings of the hard mask HM may be closed by the deposits 80.

On the other hand, if the hafnium silicate film 60 is provided near a bottom surface of the hard mask HM, an upper portion of the hard mask HM is formed only of the silicon dioxide film 55. The reaction products generated by etching are likely to adhere to upper portion openings of the hard mask HM. Therefore, the openings of the hard mask HM may be closed by the deposits 80 likewise.

Furthermore, if the hafnium silicate film 60 is located on the bottom surface of the hard mask HM, no silicon dioxide film is located between the hafnium silicate film 60 and the silicon nitride film 40. That is, the silicon dioxide film 50 is not provided and the hard mask HM is formed of the hafnium silicate film 60 and the silicon dioxide film 55. In this case, when the hard mask HM is to be removed after processing of the processing target material, the hafnium silicate film 60 cannot be removed (lifted off) through removal of the silicon dioxide film 50. That is, the hafnium silicate film 60 needs to be removed by etching. The hafnium silicate film 60 is harder to etch than a silicon dioxide film. Therefore, if the hafnium silicate film 60 is provided on the bottom surface of the hard mask HM, removal of the hard mask HM requires time.

Accordingly, in the present embodiment, the hafnium silicate film 60 is arranged almost at the central portion of the hard mask HM in the thickness direction of the hard mask HM. This prevents the hafnium silicate film 60 from being lost at the beginning of the processing step of the processing target material. When the hafnium silicate film 60 is left after processing of the processing target material, the hafnium silicate film 60 can, be removed (lifted off) at the same time as the silicon dioxide film 50 located under the hafnium silicate film 60 is removed. Therefore, the present embodiment suppresses the openings of the hard mask HM from being closed by the deposits 80 and does not elongate the manufacturing period.

Furthermore, because the reaction products of etching are likely to adhere to the upper portion openings of the hard mask HM, the hafnium silicate film 60 is located slightly above the central portion of the hard mask HM in the present embodiment as shown in FIG. 2. This can effectively suppress the upper portion openings of the hard mask HM from being closed by the deposits 80.

The position of the hafnium silicate film 60 in the thickness direction of the hard mask HM can be adjusted to enable the hafnium silicate film 60 to be removed during etching of the processing target material as shown in FIG. 4. For example, at the beginning of etching of the processing target material, the hafnium silicate film 60 needs to be left to suppress closing of the openings of the hard mask HM. However, when it is no longer necessary to care about closing of the openings of the hard mask HM at the end (a final stage) of etching of the processing target material, the hafnium silicate film 60 does not always need to be left. Therefore, the hafnium silicate film 60 can be lost at the end (the final stage) of etching of the processing target material. The position of the hafnium silicate film 60 accordingly can be adjusted to enable the hafnium silicate film 60 to be removed during etching of the processing target material.

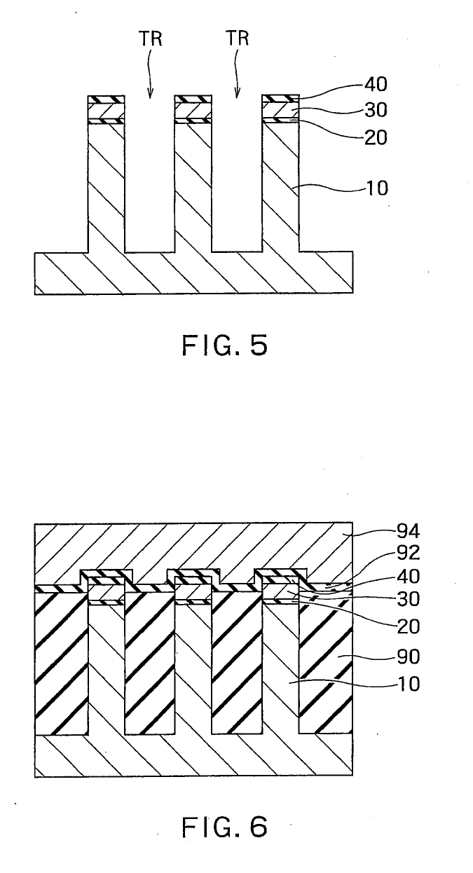

After processing the processing target material, the hard mask HM and the deposits 80 are removed by wet etching as shown in FIG. 5.

An insulating film such as a silicon dioxide film is then embedded in the trenches TR and the insulating film is etched back, whereby the STIs 90 are formed as shown in FIG. 6. An intergate dielectric film 92 is then formed on side surfaces of the polysilicon film 30 and on the STIs 90. A polysilicon film 94 is then further deposited on the intergate dielectric film 92 and is processed. In this case, the polysilicon film 30 functions as the charge accumulation layer and the polysilicon film 94 functions as control gate electrodes.

Interlayer dielectric films, contact plugs, wires, and the like (not shown) are then formed, whereby the memory according to the present embodiment is completed.

According to the present embodiment, the hafnium silicate film 60 is located almost at the central portion of the hard mask HM or slightly above the central portion of the hard mask HM in the thickness direction of the hard mask HM. This suppresses the openings of the hard mask HM from being closed by the deposits 80 and can easily remove the hard mask HM (the hafnium silicate film 60) after processing of the processing target material.

Because closing of the openings of the hard mask HM is suppressed, an etching rate (a selection ratio) of the processing target material can be increased. That is, even when an etching condition that generates many reaction products is used, the quantity of the reaction products adhering to the opening parts of the hard mask HM can be suppressed and closing of the openings of the hard mask HM can be suppressed. Because the etching rate of the processing target material can be thus increased, the film thickness of the hard mask HM can be reduced. As a result, the aspect ratio of the hard mask HM at the time of processing the processing target material can be lowered and the processing of the processing target material can be facilitated. When the aspect ratio of the hard mask HM is lowered, collapse of the pattern can be also suppressed.

### Modification of the First Embodiment

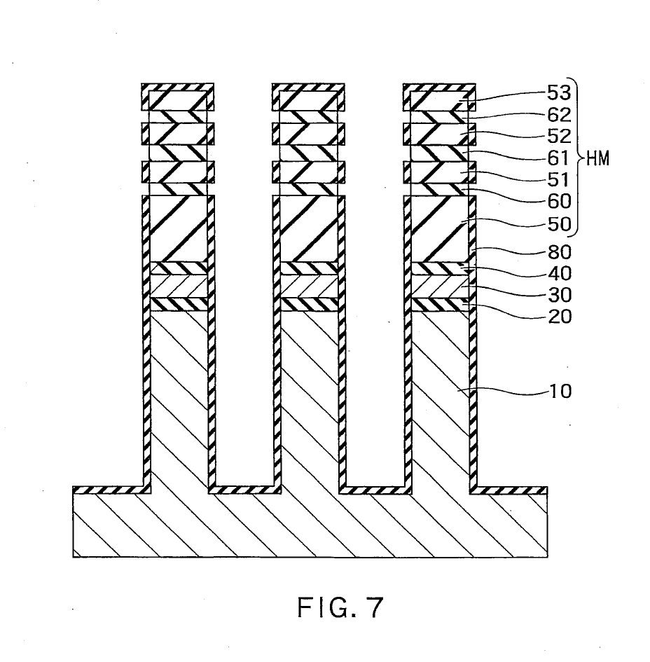

FIG. 7 is a cross-sectional view showing an example of a manufacturing method of a semiconductor device according to a modification of the first embodiment. The present modification is different from the first embodiment in that a plurality of hafnium silicate films 60 to 62 is provided in the hard mask HM. Along with this, the number of silicon dioxide films in the hard mask HM is also increased. The silicon dioxide films are denoted by reference numerals 50 to 53 in FIG. 7. That is, the hard mask HM in the present modification is formed of the silicon dioxide films 50 to 53 and the hafnium silicate films 60 to 62.

The hard mask HM is formed by depositing the silicon dioxide film 50, the hafnium silicate film 60, the silicon dioxide film 51, the hafnium silicate film 61, the silicon dioxide film 52, the hafnium silicate film 62, and the silicon dioxide film 53 in this order on the silicon nitride film 40. The steps explained with reference to FIGS. 1 to 6 are then performed to etch the processing target material using the hard mask HM as a mask.

At that time, in the course of etching the processing target material, the deposits 80 adhere to side surfaces of the silicon dioxide films 50 to 53 as shown in FIG. 7. However, not so many deposits 80 adhere to side surfaces of the hafnium silicate films 60 to 62.

The hafnium silicate films 60 to 62 are located almost at a central portion of the hard mask HM or between the central portion of the hard mask HM and an upper surface thereof in the thickness direction of the hard mask HM. For example, as shown in FIG. 7, the hafnium silicate films 60 to 62 are located slightly above the central portion of the hard mask HM. This prevents all of the hafnium silicate films 60 to 62 from being lost at the beginning of the processing step of the processing target material. Even when the hafnium silicate film 62 and/or the hafnium silicate film 61 are lost among the hafnium silicate films 60 to 62, the hafnium silicate film 60 and/or the hafnium silicate film 61 are left. Therefore, the present modification can further suppress the openings of the hard mask HM from being closed by the deposits 80.

When the hafnium silicate films 60 to 62 are left after processing of the processing target material, the hafnium silicate films 60 to 62 can be removed (lifted off) at the same time as the silicon dioxide films 50 to 52 located under the hafnium silicate films 60 to 62 are removed, respectively. Therefore, removal of the hard mask HM (the hafnium silicate films 60 to 62) after processing of the processing target material is facilitated.

As described above, even when the hafnium silicate films 60 to 62 are provided in the hard mask HM, the effect of the first embodiment is not lost. The number of the hafnium silicate films 60 to 62 in the hard mask HM is not particularly limited. Two layers of hafnium silicate films or four or more layers thereof can alternatively be provided.

### Second Embodiment

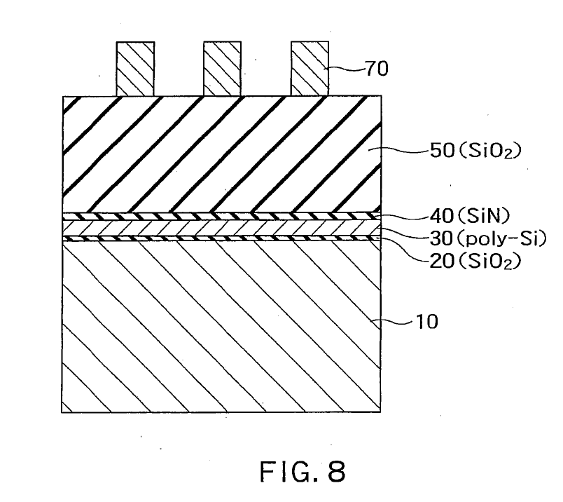

FIGS. 8 to 12 are cross-sectional views showing an example of a manufacturing method of a semiconductor device according to a second embodiment. In the first embodiment, the hafnium silicate film 60 is formed in the hard mask HM as a planar layer substantially parallel to the surface of the substrate 10. On the other hand, the hafnium silicate film 60 is formed as a side wall film provided on side surfaces of a silicon dioxide film of the hard mask HM in the second embodiment. Other manufacturing steps of the second embodiment can be identical to corresponding steps of the first embodiment.

The gate dielectric film 20, the polysilicon film 30, and the silicon nitride film 40 are first deposited on the substrate 10 as explained with reference to FIG. 1.

The silicon dioxide film 50 as a mask material is then deposited on the silicon nitride film 40. At that time, no hafnium silicate film is formed in the mask material as shown in FIG. 8. The silicon dioxide film 50 has a thickness of, for example, about 100 nanometers to 150 nanometers.

The resist 70 is then formed on the silicon dioxide film 50 by the lithography technique. At that time, the resist 70 is formed on areas where the hard mask HM is to be left similarly to the resist 70 shown in FIG. 1. For example, the resist 70 is processed in a line-and-space pattern to form the STIs and the gate electrodes. A structure shown in FIG. 8 is thereby obtained.

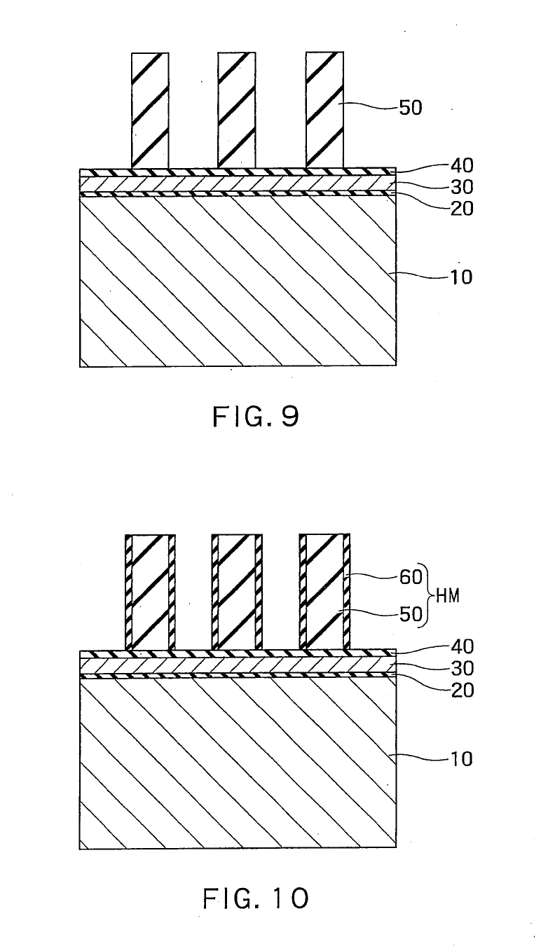

The silicon dioxide film 50 is then etched by the RIE method using the resist 70 as a mask. At that time, the silicon nitride film 40 functions as an etching stopper. The resist 70 is then removed using O₂ plasma or the like. A structure shown in FIG. 9 is thereby obtained.

The hafnium silicate film 60 is then formed on the silicon dioxide film 50 and the silicon nitride film 40 and is etched back. This causes the hafnium silicate film 60 to be left on side surfaces of the silicon dioxide film 50. The hafnium silicate film 60 has a thickness of, for example, about 5 nanometers to several tens of nanometers. A structure shown in FIG. 10 is thereby obtained. The silicon dioxide film 50 and the hafnium silicate film 60 function as the hard mask HM. The silicon dioxide film 50 and the hafnium silicate film 60 are hereinafter also referred to as “hard mask HM”.

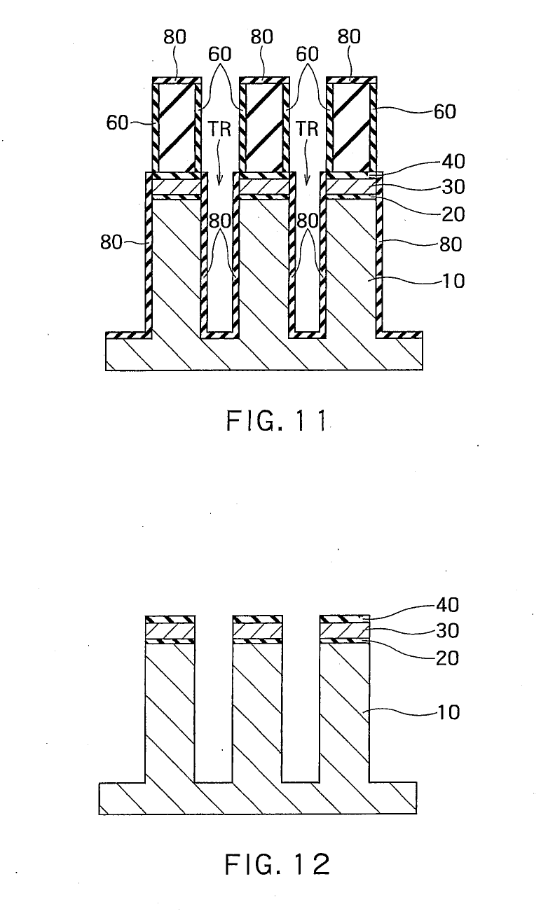

The silicon nitride film 40, the polysilicon film 30, the gate dielectric film 20, and the substrate 10 (hereinafter, also collectively as “processing target material”) are then etched by the RIE method using the hard mask HM as a mask. Reaction products are generated when the processing target material is etched and the reaction products adhere as deposits (etching residues) 80 to side walls of the trenches TR and upper surfaces of the silicon dioxide film 50 as shown in FIG. 11. Etching gas contains at least HBr and O₂ and is, for example, CF-based gas. In this case, the deposits 80 are CF-based deposits and deposits containing a silicon oxide.

As shown in FIG. 11, while a relatively large quantity of deposits 80 adhere to side surfaces of the processing target material and the upper surfaces of the silicon dioxide film 50, not so many deposits 80 adhere to the hafnium silicate film 60. A film thickness of the deposits 80 adhering to the hafnium silicate film 60 is possibly smaller than that of the deposits 80 adhering to the side surfaces of the processing target material and the upper surfaces of the silicon dioxide film 50. Therefore, the deposits 80 hardly adhere to the entire side surfaces of the hard mask HM (the silicon dioxide film 50) or are formed thin. This suppresses closing of the openings of the hard mask HM more effectively.

After processing the processing target material, the hard mask HM is removed by wet etching or dry etching as shown in. FIG. 12. At that time, because the hafnium silicate film 60 is deposited on the side surfaces of the silicon dioxide film 50, the hafnium silicate film 60 can be removed (lifted off) easily through removal of the silicon dioxide film 50. The deposits 80 adhering to the processing target material are then removed by wet etching. A structure shown in FIG. 12 is thereby obtained.

The STIs 90, the intergate dielectric film 92, and the polysilicon film 94 are then formed as explained with reference to FIG. 6. Interlayer dielectric films, contact plugs, wires, and the like (not shown) are further formed, whereby the memory according to the present embodiment is completed.

According to the second embodiment, the hafnium silicate film 60 covers the entire side surfaces of the hard mask HM (the silicon dioxide film 50). This enables to suppress the openings of the hard mask HM from being closed by the deposits 80. Furthermore, the hafnium silicate film 60 is provided on the side surfaces of the hard mask HM (the silicon dioxide film 50) and has less contact with the processing target material. Therefore, the hard mask HM (the hafnium silicate film 60) can be easily removed after processing of the processing target material.

Because closing of the openings of the hard mask HM is suppressed in the second embodiment, the etching rate (the selection ratio) of the processing target material can be increased. Accordingly, the film thickness of the hard mask HM can be reduced. As a result, the aspect ratio of the hard mask HM at the time of processing the processing target material can be lowered and processing of the processing target material can be facilitated. Furthermore, collapse of the pattern can be suppressed.

The first and second embodiments can be combined with each other.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A manufacturing method of a semiconductor device, the method comprising:
forming a mask material comprising at least one layer of a hafnium silicate (HfSiOn (n is a positive number)) film on a processing target material; and
processing the processing target material using the mask material as a mask, wherein
the hafnium silicate film is located almost at a central portion of the mask material or between the central portion of the mask material and an upper surface thereof.

2. The method of claim 1, wherein the mask material is formed of the hafnium silicate film and a silicon dioxide film.

3. The method of claim 1, wherein the mask material has a plurality of the hafnium silicate films.

4. The method of claim 2, wherein the mask material has a plurality of the hafnium silicate films.

5. The method of claim 1, wherein etching gas used at a time of processing the processing target material comprises at least HBr and O₂.

6. The method of claim 2, wherein etching gas used at a time of processing the processing target material comprises at least HBr and O₂.

7. The method of claim 1, wherein forming of the mask material comprises:
depositing a first mask material on the processing target material;
depositing the hafnium silicate film on the first mask material;
depositing a second mask material on the hafnium silicate film; and
processing the first mask material, the hafnium silicate film, and the second mask material into a desired pattern.

8. A manufacturing method of a semiconductor device, the method comprising:
forming a mask material on a processing target material;
forming a hafnium silicate (HfSiOn (n is a positive number)) film on side walls of the mask material; and
processing the processing target material using the mask material and the hafnium silicate film as a mask.

9. The method of claim 8, wherein the mask material is formed of a silicon dioxide film.

10. The method of claim 8, wherein etching gas used at a time of processing the processing target material comprises at least HBr and O₂.

11. The method of claim 9, wherein etching gas used at a time of processing the processing target material comprises at least HBr and O₂.
